(19) United States
(12) Patent Application Publication
(10) Pub. No.: US 2026/0177586 A1
(43) Pub. Date: Jun. 25, 2026

(54) NANOPROBE MANUFACTURING MACHINE AND METHOD OF MANUFACTURING NANOPROBE

(71) Applicant: United Microelectronics Corp., Hsinchu (TW)

(72) Inventors: Zhe Wang, Singapore (SG); Lu Zou, Singapore (SG); Yikun Chen, Singapore (SG)

(73) Assignee: United Microelectronics Corp., Hsinchu (TW)

(21) Appl. No.: 18/986,710

(22) Filed: Dec. 19, 2024

(51) Int. Cl. G01R 1/067

(52) U.S. Cl. CPC G01R 1/06755; G01R 1/06705

(57) ABSTRACT

A nanoprobe manufacturing machine and a method of manufacturing nanoprobe are provide. The nanoprobe manufacturing machine comprising a step motor held by a hold stage and is removable in an upward direction and in a downward direction; a positive electrode and a negative electrode respectively fixed on the step monitor; a first metal probe fixed and electrically connected to the positive electrode and a second metal probe fixed and electrically connected to the negative electrode; and a container containing an electrolyte, wherein the step motor carrying the first metal probe and the second metal probe into the electrolyte to form a nanoprobe from the first metal probe by a redox reaction in the electrolyte.

### BACKGROUND

### Technical Field

The disclosure relates to a nanoprobe, and particularly relates to a nanoprobe manufacturing machine and a method of manufacturing nanoprobe.

### Description of Related Art

In the semiconductor manufacturing process, the electrical measurement and identifying defects by nanoprobe is one of the main method to monitor the manufacturing process and measure electrical properties of final products. For example, by using the nanoprobes to contact directly the gate, the drain, the source and the substrate of the transistor, and supplying voltage and current through the nanoprobes, the electrical diagrams of the transistor, such as IV curve, of the devices, are measured. The important device parameters, such as threshold voltage (Vth), saturation current (Isat), etc., could be obtained from those electrical diagrams.

However, the commercially available nanoprobes not only have fixed size limitations, but are also expensive. Since multiple nanoprobes are required in the several times of electrical measurements in the semiconductor manufacturing process, the cost of the nanoprobes is considerable.

### SUMMARY

Therefore, the disclosure use a nanoprobe manufacturing machine for low cost nanoprobe manufacture.

The disclosure provides a nanoprobe manufacturing machine, a step motor held by a hold stage and is removable in an upward direction and in a downward direction; a positive electrode and a negative electrode respectively fixed on the step monitor; a first metal probe fixed and electrically connected to the positive electrode and a second metal probe fixed and electrically connected to the negative electrode; and a container containing an electrolyte, wherein the step motor carrying the first metal probe and the second metal probe into the electrolyte to form a nanoprobe from the first metal probe by a redox reaction in the electrolyte.

In an embodiment of the nanoprobe manufacturing machine of the disclosure, the first metal probe comprises a metal, an alloy or a doped metal.

In an embodiment of the nanoprobe manufacturing machine of the disclosure, the first metal probe comprises tungsten (W), rhenium tungsten (ReW), beryllium copper (BeCu), high carbon steel, brass, nickel silver, palladium (Pd) alloy, bronze or K-doped tungsten.

In an embodiment of the nanoprobe manufacturing machine of the disclosure, the second metal probe comprises a metal, an alloy or a doped metal.

In an embodiment of the nanoprobe manufacturing machine of the disclosure, the second metal probe comprises tungsten (W), rhenium tungsten (ReW), beryllium copper (BeCu), high carbon steel, brass, nickel silver, palladium (Pd) alloy, bronze or K-doped tungsten.

In an embodiment of the nanoprobe manufacturing machine of the disclosure, a tip size of the nanoprobe is 10 nm-120 nm.

In an embodiment of the nanoprobe manufacturing machine of the disclosure, the electrolyte comprises an alkaline solution.

In an embodiment of the nanoprobe manufacturing machine of the disclosure, the alkaline solution comprises potassium hydroxide (KOH).

The disclosure provides a method of manufacturing nanoprobe, comprising: preparing a first metal probe and a second metal probe; fixing and electrically connecting respectively the first metal probe to a positive electrode, and fixing and electrically connecting a second metal probe to a negative electrode, wherein the positive electrode and the negative electrode are fixed on a step monitor holding by a hold stage; moving down the step motor for displacing the first metal probe and the second metal probe into an electrolyte in a container; and performing a redox reaction in the electrolyte to form a nanoprobe from the first metal probe.

In an embodiment of the method of manufacturing nanoprobe of the disclosure, the preparation of the first metal probe comprises cutting a first metal wire into a first suitable length, and the preparation of the second metal probe comprises cutting a second metal wire into a second suitable length.

In an embodiment of the method of manufacturing nanoprobe of the disclosure, the first suitable length is 15 cm-20 cm.

In an embodiment of the method of manufacturing nanoprobe of the disclosure, the second suitable length is 15 cm-20 cm.

In an embodiment of the method of manufacturing nanoprobe of the disclosure, the first metal probe comprises a metal, an alloy or a doped metal.

In an embodiment of the method of manufacturing nanoprobe of the disclosure, the first metal probe comprises tungsten (W), rhenium tungsten (ReW), beryllium copper (BeCu), high carbon steel, brass, nickel silver, palladium (Pd) alloy, bronze or K-doped tungsten.

In an embodiment of the method of manufacturing nanoprobe of the disclosure, the second metal probe comprises a metal, an alloy or a doped metal.

In an embodiment of the method of manufacturing nanoprobe of the disclosure, the second metal probe comprises tungsten (W), rhenium tungsten (ReW), beryllium copper (BeCu), high carbon steel, brass, nickel silver, palladium (Pd) alloy, bronze or K-doped tungsten.

In an embodiment of the method of manufacturing nanoprobe of the disclosure, a tip size of the nanoprobe is 10 nm-120 nm.

In an embodiment of the method of manufacturing nanoprobe of the disclosure, the electrolyte comprises an alkaline solution.

In an embodiment of the method of manufacturing nanoprobe of the disclosure, the alkaline solution comprises potassium hydroxide (KOH).

Based on the above, a nanoprobe may be easily obtained with low cost and high quality. Furthermore, because the nanoprobe is manufacturing by a redox reaction, the profile thereof could be etched in a very fine way. The size of the nanoprobe may be also adjusted according to the size of the semiconductor device using the above-mentioned machines and forming method.

### BRIEF DESCRIPTION OF THE DRAWINGS

FIG. 1 is a schematic views of a nanoprobe manufacturing machine.

FIG. 2 is a schematic views of a nanoprobe manufacturing machine after performing a redox reaction.

### DESCRIPTION OF THE EMBODIMENTS

Hereinafter, exemplary embodiments will be described in detail with reference to the accompanying drawings, but the provided embodiments are not intended to limit the scope of the disclosure. In addition, the drawings are for illustrative purposes only and may not be drawn to scale.

Terms such as “containing”, “including”, “having”, etc. used in this specification are all open-ended terms, that is, meaning “including but not limited to”.

When terms such as “first,” “second,” etc. are used to describe the elements, they are only used to distinguish these elements from each other and are not intended to limit the order or importance of the elements. Therefore, in some cases, the first element may also be referred to as the second element, and the second element may also be referred to as the first element, without departing from the scope of the disclosure.

In addition, directional terms such as “up”, “down”, etc. used in this specification only refer to the directions of the drawings and are not intended to limit the disclosure.

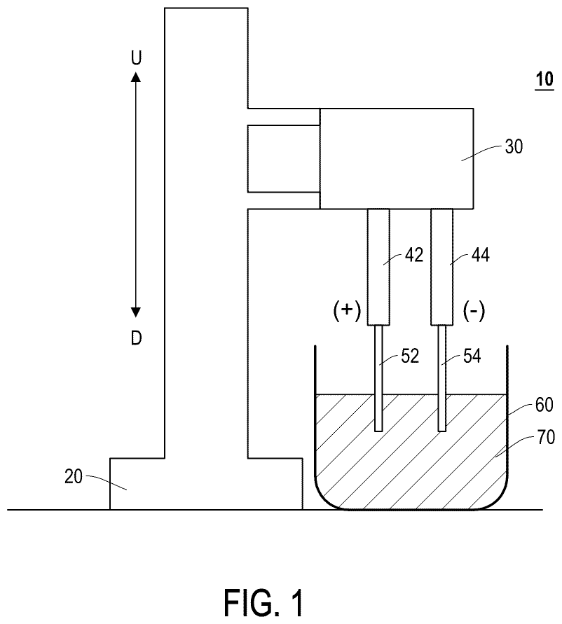

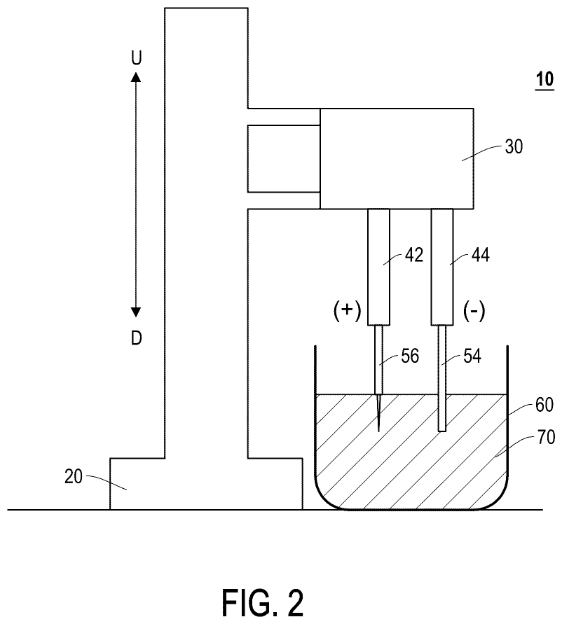

FIG. 1 is a schematic views of a nanoprobe manufacturing machine 10. FIG. 2 is a schematic views of a nanoprobe manufacturing machine 10 after performing a redox reaction. In fact, the two drawings show the same nanoprobe manufacturing machine 10, the difference just lies in the reactant before the reaction and the product after the reaction. So the same symbols are marked for the same elements of the nanoprobe manufacturing machine 10.

Firstly, please refer to nanoprobe manufacturing machine 10 shown in FIG. 1, which includes a step motor 30 held by a hold stage 20, and the step motor 30 is removable in an upward direction U and in a downward direction D.

Continue referring to FIG. 1, a positive electrode 42 and a negative electrode 44 are respectively fixed on the step monitor 30. The positive electrode 42 and the negative electrode 44 are supplied with a DC (direct current) power.

Continue referring to FIG. 1, a first metal probe 52 is fixed and electrically connected to the positive electrode 42, and a second metal probe 54 is fixed and electrically connected to the negative electrode 44.

The first metal probe 52 may be prepared, for example, but is not limited thereto, by cutting a first metal wire into a first suitable length. The second metal probe 54 may be prepared, for example, but is not limited thereto, by cutting a second metal wire into a second suitable length.

In some embodiments, based on the cost down considerations, the first metal wire and the second metal wire may be a commercially available wire respectively, but are not limited thereto. Any suitable wire for manufacturing the nanoprobe could use the disclosure.

The first suitable length and the second suitable length are determined by the arrangement of the nanoprobe manufacturing machine and requirements for the machine using the nanoprobe. For example, the first suitable length is about 15 cm-about 20 cm. The second suitable length is about 15 cm-about 20 cm. The first suitable length and the second suitable length are the same or different. After the manufacturing process, the nanoprobe 56, shown in FIG. 2 may be used only the about 2 cm-about 3 cm tip in the measurement, for example, but is not limited thereto.

In addition, the material of the first metal probe 52 and the second metal probe 54 may be chosen according to the requirement of the material of the nanoprobe. The material of the first metal probe 52 and the second metal probe 54 may comprise respectively a metal, an alloy or a doped metal. For example, the material of the first metal probe 52 and the second metal probe 54 may comprise respectively tungsten (W), rhenium tungsten (ReW), beryllium copper (BeCu), high carbon steel, brass, nickel silver, palladium (Pd) alloy, bronze or K-doped tungsten. The material of the first metal probe 52 and the second metal probe 54 may be chosen based on the material of the nanoprobe. Taking a tungsten (W) nanoprobe for example, which is softer and has the smaller contact resistant to form an ideal contact with the chip without damage, the first metal probe 52 may comprise tungsten, rhenium tungsten (ReW) or K-doped tungsten, but are not limited thereto. The material the second metal probe 54 may comprise tungsten, rhenium tungsten (ReW) or K-doped tungsten, but are not limited thereto. The material of the first metal probe 52 and the material the second metal probe 54 may be the same or different.

A diameter of the first metal probe 52 and a diameter of the second metal probe 54 may be chosen from the commercially available wire based on the required diameter of the nanoprobe 56, shown in FIG. 2. For example, the diameter of the first metal probe 52 is about 60 nm-about 100 nm, and the diameter of the second metal probe 54 is about 40 nm-about 80 nm. The diameter of the first metal probe 52 needs more consideration than the diameter of the second metal probe 54. If the diameter of the first metal probe 52 is too large, the time of the following-mentioned redox reaction will take too long. If the diameter of the first metal probe 52 is too small, the profile of the nanoprobe 56, shown in FIG. 2, is harder to control.

Continue referring to FIG. 1, a container 60 contains an electrolyte 70. The container may be any kind of container that may contain the electrolyte, for example, a beaker. The choice of the electrolyte 70 depends on the reacting metal. Any suitable electrolyte 70 may be used in the disclosure. For example, but is not limited, the electrolyte 70 comprises an alkaline solution, for example, potassium hydroxide (KOH) solution.

Continue referring to FIG. 1, the step motor 30, carrying the first metal probe 52 and the second metal probe 54, is moved from the upward direction U to the downward direction D in a movement rate, for displacing the first metal probe 52 and the second metal probe 54 into the electrolyte 70 in the container 60. For example, the movement rate is about 0.0125 mm/s-about 0.083 mm/s, but is not limited thereto. The specific movement rate can be adjusted according to the machine and the size of the tip of the nanoprobe 56, shown in FIG. 2. In the electrolyte 70, the first metal probe 52 becomes a nanoprobe 56, shown in FIG. 2, by performing a redox reaction in the electrolyte 70 in a charging process. The charging process is contributed form the DC power connecting to the positive electrode 42 and the negative electrode 44.

During the charging process, the first metal probe 52 connected to the positive electrode 42 is an anode. An oxidation reaction occurs on the first metal probe 52. On the other hand, the second metal probe 54 connected to the negative electrode 44 is a cathode. A reduction reaction occurs on the second metal probe 54. When the oxidation reaction occurs, the first metal of the first metal probe 52 dip in the electrolyte 70 losses electrons, becomes metal ion and solves into the electrolyte 70. This microscopic phenomenon of metal loss may be considered a form of etching. The nanoprobe 56 is gradually formed form the first metal probe 52 by the etching process.

In addition, the deeper first metal probe 52 dip into the electrolyte 70 and the longer reaction time of the redox reaction, the metal of the first metal probe 52 losses more into the electrolyte 70. In addition, the movement rate of moving down the first metal probe 52 into the electrolyte 70 affects also etching process. Accordingly, the profile of the nanoprobe 56 may be controlled at least by the depth of the first metal probe 52 dip into the electrolyte 70, the movement rate of moving down the first metal probe 52 into the electrolyte 70, the reaction time of the redox reaction of the first metal probe 52 and the second metal probe 54 in the electrolyte 70 and the concentration of the electrolyte 70, etc. Thus, the diameter of the first metal probe 52 may be controlled to nano-scale, then the nanoprobe 56 is formed.

The nanoprobe 56 obtained by the disclosure has a smooth surface. In addition, because the tip size of the nanoprobe 56 is about 10 nm-about 120 nm, which may be used in the current technology and in the advanced technology. Furthermore, the IV curve is successfully measured.

By using the new design nanoprobe manufacturing machine and the method of manufacturing nanoprobe above-mentioned of the disclosure, a nanoprobe may be easily obtained with low cost and high quality. Furthermore, because the nanoprobe is manufacturing by a redox reaction, the profile thereof could be etched in a very fine way. The size of the nanoprobe may be also adjusted according to the size of the semiconductor device using the above-mentioned machines and forming method.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A nanoprobe manufacturing machine, comprising:
a step motor held by a hold stage and is removable in an upward direction and in a downward direction;
a positive electrode and a negative electrode respectively fixed on the step monitor;
a first metal probe fixed and electrically connected to the positive electrode and a second metal probe fixed and electrically connected to the negative electrode; and
a container containing an electrolyte, wherein
the step motor carrying the first metal probe and the second metal probe into the electrolyte to form a nanoprobe from the first metal probe by a redox reaction in the electrolyte.

2. The nanoprobe manufacturing machine according to claim 1, wherein the first metal probe comprises a metal, an alloy or a doped metal.

3. The nanoprobe manufacturing machine according to claim 2, wherein the first metal probe comprises tungsten (W), rhenium tungsten (ReW), beryllium copper (BeCu), high carbon steel, brass, nickel silver, palladium (Pd) alloy, bronze or K-doped tungsten.

4. The nanoprobe manufacturing machine according to claim 1, wherein the second metal probe comprises a metal, an alloy or a doped metal.

5. The nanoprobe manufacturing machine according to claim 4, wherein the second metal probe comprises tungsten (W), rhenium tungsten (ReW), beryllium copper (BeCu), high carbon steel, brass, nickel silver, palladium (Pd) alloy, bronze or K-doped tungsten.

6. The nanoprobe manufacturing machine according to claim 1, wherein a tip size of the nanoprobe is 10 nm-120 nm.

7. The nanoprobe manufacturing machine according to claim 1, wherein the electrolyte comprises an alkaline solution.

8. The nanoprobe manufacturing machine according to claim 7, wherein the alkaline solution comprises potassium hydroxide (KOH).

9. A method of manufacturing nanoprobe, comprising:
preparing a first metal probe and a second metal probe;
fixing and electrically connecting respectively the first metal probe to a positive electrode, and fixing and electrically connecting a second metal probe to a negative electrode, wherein the positive electrode and the negative electrode are fixed on a step monitor holding by a hold stage;
moving down the step motor for displacing the first metal probe and the second metal probe into an electrolyte in a container; and
performing a redox reaction in the electrolyte to form a nanoprobe from the first metal probe.

10. The method of manufacturing nanoprobe according to claim 9, wherein the preparation of the first metal probe comprises cutting a first metal wire into a first suitable length, and the preparation of the second metal probe comprises cutting a second metal wire into a second suitable length.

11. The method of manufacturing nanoprobe according to claim 10, wherein the first suitable length is 15 cm-20 cm.

12. The method of manufacturing nanoprobe according to claim 10, wherein the second suitable length is 15 cm-20 cm.

13. The method of manufacturing nanoprobe according to claim 9, wherein the first metal probe comprises a metal, an alloy or a doped metal.

14. The method of manufacturing nanoprobe according to claim 13, wherein the first metal probe comprises tungsten (W), rhenium tungsten (ReW), beryllium copper (BeCu), high carbon steel, brass, nickel silver, palladium (Pd) alloy, bronze or K-doped tungsten.

15. The method of manufacturing nanoprobe according to claim 9, wherein the second metal probe comprises a metal, an alloy or a doped metal.

16. The method of manufacturing nanoprobe according to claim 15, wherein the second metal probe comprises tungsten (W), rhenium tungsten (ReW), beryllium copper (BeCu), high carbon steel, brass, nickel silver, palladium (Pd) alloy, bronze or K-doped tungsten.

17. The method of manufacturing nanoprobe according to claim 9, wherein a tip size of the nanoprobe is 10 nm-120 nm.

18. The method of manufacturing nanoprobe according to claim 9, wherein the electrolyte comprises an alkaline solution.

19. The method of manufacturing nanoprobe according to claim 18, wherein the alkaline solution comprises potassium hydroxide (KOH).
